(19) United States
(12) Patent Application Publication
(10) Pub. No.: US 2005/0024083 A1
(43) Pub. Date: Feb. 3, 2005

(54) Electronic device with serial ATA interface and signal amplitude automatic adjustment method

(75) Inventors: Shunichi Kitamura, Ome-shi (JP); Fubito Igari, Hamura-shi (JP)

Correspondence Address: FOLEY & LARDNER, 2029 CENTURY PARK EAST, SUITE 3500, LOS ANGELES, CA, 90067, US

(73) Assignee: KABUSHIKI KAISHA TOSHIBA

(21) Appl. No.: 10/909,208

(22) Filed: Jul. 29, 2004

(30) Foreign Application Priority Data
Jul. 31, 2003 (JP) 2003-283707

(51) Int. Cl. H03K 17/16

(52) U.S. Cl. 326/21

(57) ABSTRACT

An amplitude detector incorporated in an electronic device with a serial ATA interface detects the amplitude of a serial data signal input to an I/O circuit via a SATA bus. An averaging unit averages the detection results of the amplitude detector. A comparator compares the resultant average with an expected input signal amplitude. Based on the comparison result, an amplitude adjuster adjusts the amplitude of a serial data signal when this signal is output from the I/O circuit. Adjustment is performed such that when the serial data signal output from the I/O circuit is input to another electronic device via the SATA bus, it has an amplitude at least approximately equal to the expected input signal amplitude. In other embodiments, the invention utilizes an amplitude detector, comparator and adjuster and employs a step-by-step adjustment of the electronic device with another similarly equipped electronic device.

### CROSS-REFERENCE TO RELATED APPLICATIONS

This application is based upon and claims the benefit of priority from prior Japanese Patent Application No. 2003-283707, filed Jul. 31, 2003, the entire contents of which are incorporated herein by reference.

### BACKGROUND OF THE INVENTION

1. Field of the Invention

The present invention relates to an electronic device for serially transferring data using a serial ATA (Advanced Technology Attachment) interface. More particularly, it relates to an electronic device and signal amplitude automatic adjustment method utilizing a serial ATA interface suitable for automatically adjusting the amplitude of a serial data signal, output to a serial ATA bus, in light of the signal attenuation of the serial ATA bus.

2. Description of the Related Art

At present, standards for serial ATA interfaces as a new type of interface for use in disk drives are now being worked out. Serial ATA interfaces are used as an interface between a peripheral device, represented by a magnetic disk drive, and a host (host system) represented by a personal computer. In this point, serial ATA interfaces are similar to conventional ATA interfaces (i.e., parallel ATA interfaces).

A peripheral device with a serial ATA interface, such as a magnetic disk drive (hereinafter referred to as an “HDD”), is connected to a host by a serial bus. In such an HDD, to secure compatibility with an ATA interface, it is necessary to convert an ATA interface into a serial ATA interface, and convert a serial ATA interface into an ATA interface. Such interface conversion is performed by, for example, an LSI (bridge LSI) called a serial ATA bridge.

In the serial ATA interface standards, three layers of different functions, i.e., a physical layer, link layer and transport layer, are defined. The physical layer has a function for executing high-rate serial data transmission and reception. The physical layer interprets received data, and transmits the data to the link layer in accordance with an interpretation result. The physical layer also outputs a serial data signal to the link layer in response to a request therefrom. The link layer supplies the physical layer with a request to output a signal. The link layer also supplies the transport layer with the data transmitted from the physical layer. The transport layer performs conversion for operations based on the ATA standards. Assuming that the above-mentioned bridge LSI is used in an HDD, the role of the transport layer corresponds to the role of the ATA signal output unit of a conventional host that utilizes ATA connection. The bridge LSI is connected to the disk controller (HDC) of the HDD via an ATA bus (or a bus compliant with the ATA bus) based on the ATA interface standards. Accordingly, in the connection between the bridge LSI and HDC of the HDD, operations equivalent to those stipulated in the ATA interface standards or compatible with the standards are performed. In this case, the portion of the HDD excluding the bridge LSI (hereinafter referred to as a “main HDD unit”) regards the bridge LSI as an apparatus (host) for issuing a command to the main HDD unit. Accordingly, the main HDD unit operates in the same manner as a conventional HDD utilizing ATA connection. Thus, the serial ATA interface has compatibility with the ATA standards concerning protocols such as logical commands. However, a data signal (parallel data signal) processed by a parallel ATA interface must be converted into a serial data signal.

The serial ATA interface standards stipulate that a cable with a length of 1 m, at maximum, can be used for data transfer using a serial ATA interface. Further, the serial ATA interface standards sets the maximum and minimum amplitudes of a signal at the receive side to 600 mV and 325 mV, respectively. Actually, however, when apparatuses are connected using a serial ATA interface, attenuation in a data signal due to the cable (serial ATA bus) used must be considered. That is, a data signal output from a transmitter that uses a serial ATA interface attenuates while passing through the cable (serial ATA bus). As a result, the amplitude of the data signal is inevitably reduced when it is received by a receiver. Thus, when the amplitude of a signal output from a transmitter is determined so that at the receive side, it falls within the range stipulated in the serial ATA interface standards, attenuation due to the cable must be considered.

Assume here that the amplitude of a signal output from a transmitter is set in light of maximum signal attenuation that occurs when a cable of 1 m is connected between the transmitter and receiver, so that at the receive side, it falls within the standard range. Assume also that the transmitter is actually connected to the receiver by a very short cable (serial ATA bus). In this case, the attenuation of a signal due to the cable is smaller than the assumed maximum attenuation, therefore the actual signal amplitude at the receiver is higher than in the maximum signal attenuation case. As a result, the amplitude of a signal received may well be higher than the reference (standard) value, which may adversely influences the receiver. On the other hand, if a long cable is used where the amplitude of a signal output from a transmitter is set in light of a short cable, the amplitude of a signal received may be lower than the reference value.

The above-described case where an assumed cable length differs from an actual one can occur when the apparatus to which a serial ATA interface is connected is, for example, a small-size HDD (magnetic disk drive). This is for the following reasons: Firstly, a small-size HDD can be used not only as a storage for a desktop computer, like a large-size HDD, but also as a storage for a portable electronic device, such as a notebook-type personal computer. Thus, a small-size HDD can be used in various occasions. If an HDD is used as a storage for a portable electronic device, the space for the HDD is generally small. In this case, the degree of freedom of selecting the length of a cable connected between the HDD and electronic device is low. For example, if a 2.5-inch HDD is used as a storage for a notebook-type personal computer, the HDD is directly connected to the computer without a cable. Thus, in the case of a small HDD, it is necessary to change the length of the cable used, depending upon the situation. In other words, the cable length cannot be set in advance. This raises the above-mentioned case where the assumed cable length differs from the actual one.

Jpn. Pat. Appln. KOKAI publication No. 2000-13283 (hereinafter referred to as a “prior art document”) discloses a system equipped with a signal transmission device capable of automatically adjusting an output signal level regardless of a cable length employed. In this system, a training signal is output from a vendor device (first signal transmission unit) to a user device (second signal transmission unit) before actual data communication. The transmission level of the training signal is set to a maximum level preset between the vendor device and user device. The user device detects the reception level of the training signal, thereby estimating the signal attenuation of a signal transmission line. Based on the signal attenuation and the reception sensitivity of the vendor device, the user device determines an actual transmission level for data communication. More specifically, the transmission level is determined so that the level of a signal, which has been output from the user device and has reached the vendor device, is equal to the minimum signal level that can be received by the vendor device. At this time, the user device transmits a training signal of a maximum level to the vendor device. The vendor device estimates, from the reception level of the training signal, the signal attenuation of the signal transmission line. Based on the signal attenuation and the reception sensitivity of the user device, the vendor device determines an actual transmission level for data communication. More specifically, the transmission level is determined so that the level of a signal, which has been output from the vendor device and has reached the user device, is equal to the minimum signal level that can be received by the user device.

As described above, in the signal transmission device described in the prior art document, when a training signal of a preset level is transmitted from another device to the signal transmission device via a transmission line, the signal attenuation of the transmission line is estimated from the reception level of the signal. Based on the estimation result, the transmission level of a signal output from the signal transmission device is determined. It is possible to employ the transmission level automatic adjustment technique, described in the prior art document, in a system in which apparatuses therein are connected via a serial ATA interface.

However, the prior art document merely describes that the transmission level is determined so that the reception level assumed when a signal output from the signal transmission device has reached another device via the transmission line is equal to the minimum signal level that can be received by said other device. On the other hand, the serial ATA interface standards stipulate the maximum and minimum amplitudes of a signal input to (received by) a receiver. Therefore, even if the prior art is applied to a system in which apparatuses therein are connected via a serial ATA interface, it is not easy to make the amplitude of an input signal (received signal) at the receive side fall within the standard range. Moreover, since the level (amplitude) of a input signal (received signal) fluctuates, the estimated signal attenuation varies depending upon the signal level detection time. Therefore, in the prior art, the determined transmission level may fall outside the range stipulated in the serial ATA interface standards, depending upon the signal level detection time.

### BRIEF SUMMARY OF THE INVENTION

An embodiment of the invention is directed toward an electronic device with a serial ATA interface having a signal output device for outputting a serial data signal to a serial ATA bus connecting the electronic device to another electronic device. The serial data signal is to be transferred to the another electronic device which also has a serial ATA interface. A signal input device is provided in the electronic device for receiving a serial data signal transferred from the another electronic device via the serial ATA bus. Also provided are a peak detection circuit, an averaging circuit, a comparison circuit and an amplitude adjuster. The peak detection circuit detects an amplitude of the serial data signal received by the signal input device. The averaging circuit averages the amplitude detection results of the peak detection circuit. The comparison device compares the averaging result of the averaging circuit with an expected input signal amplitude; and the amplitude adjuster adjust, based on a comparison result of the comparison device, an amplitude of the serial data signal output by the signal output device such that when the serial data signal output from the signal output device is input to the another electronic device via the serial ATA bus, the input serial data signal has an amplitude at least approximately equal to the expected input signal amplitude.

In accordance with other embodiments of the invention there is provided a system comprising having a first electronic device having a serial ATA interface; a second electronic device having a serial ATA interface; and a serial ATA bus connecting the first electronic device to the second electronic device. The first electronic device includes a first signal output device for outputting, to the serial ATA bus, a serial data signal to be transferred to the second electronic device; a first signal input device for receiving a serial data signal transferred from the second electronic device via the serial ATA bus; a first peak detection circuit for detecting an amplitude of the serial data signal received by the first signal input device; a first averaging circuit for averaging amplitude detection results of the first peak detection circuit; a first comparison device for comparing an averaging result of the first averaging circuit with an expected input signal amplitude determined from a reference input signal amplitude for the serial ATA interfaces; and a first amplitude adjuster for adjusting, based on a comparison result of the first comparison device, an amplitude of the serial data signal output by the first signal output device such that when the serial data signal output from the first signal output device is input to the second electronic device via the serial ATA bus, the input serial data signal has an amplitude at least approximately equal to the expected input signal amplitude.

Further the second electronic device includes a second signal output device for outputting, to the serial ATA bus, the serial data signal output by the second signal output device; a second signal input device for receiving the serial data signal output from the first signal output device via the serial ATA bus; a second peak detection circuit for detecting an amplitude of the serial data signal received by the second signal input device; a second averaging circuit for averaging amplitude detection results of the second peak detection circuit; a second comparison device for comparing an averaging result of the second averaging circuit with the expected input signal amplitude; and a second amplitude adjuster for adjusting, based on a comparison result of the second comparison device, an amplitude of serial data signal output by the second signal output device such that when the serial data signal output from the second signal output device is input to the first electronic device via the serial ATA bus, the input serial data signal has an amplitude at least approximately equal to the expected input signal amplitude.

Yet another embodiment of the invention is characterized as a method of automatically adjusting an output signal amplitude. The method is employed in a system in which a first electronic device with a serial ATA interface is connected to a second electronic device with a serial ATA interface via a serial ATA bus, the first electronic device including a signal output device for outputting a serial data signal to the serial ATA bus, and a signal input device for receiving a serial data signal transferred from the second electronic device via the serial ATA bus, the output signal amplitude being an amplitude of the serial data signal output from the signal output device to the serial ATA bus. The method encompasses detecting an amplitude of the serial data signal received by the signal input device, at a sampling frequency, the detecting performed during a predetermined time period; averaging amplitudes detected during the predetermined period; comparing an average acquired by the averaging with an expected input signal amplitude determined from a reference input signal amplitude for the serial ATA interfaces to produce a comparison result; and adjusting, based on the comparison result, an amplitude of a serial data signal output from the signal output device, such that when the serial data signal output from the signal output device is input to the second electronic device via the serial ATA bus, the input serial data signal has an amplitude at least approximately equal to the expected input signal amplitude.

The invention may further be characterized in accordance with another embodiment of the invention as an electronic device with a serial ATA interface having a signal output device for outputting a serial data signal to a serial ATA bus connecting the electronic device to another electronic device, the serial data signal to be transferred to the another electronic device. The another electronic device has a serial ATA interface; a signal input device for receiving a serial data signal transferred from the another electronic device via the serial ATA bus; a detection circuit for detecting an amplitude of the serial data signal received by the signal input device; a comparison device for comparing the detected amplitude with an expected input signal amplitude; and an amplitude adjuster for determining, based on a comparison result of the comparison device, an amplitude A of the serial data signal output by the signal output device such that when the serial data signal output from the signal output device is input to the another electronic device via the serial ATA bus, the input serial data signal has an amplitude approximately equal to the expected input signal amplitude, the amplitude adjuster multiplying the amplitude A by a coefficient less than one so that the input serial data signal amplitude is CA which is less than the expected input signal amplitude.

Embodiments of the invention are directed toward a method of automatically adjusting an output signal amplitude. The method is employed in a system in which a first electronic device with a serial ATA interface is connected to a second electronic device with a serial ATA interface via a serial ATA bus, the first electronic device including a first signal output device, and a first signal input device, and the second electronic device including a second signal output device, and a second signal input device. The method includes (a) transmitting a serial data signal Si from the second signal output device to the first signal input device over the serial ATA bus; (b) detecting an amplitude of the serial data signal S1 received by the first signal input device from the second signal output device; (c) comparing the detected amplitude with an expected input signal amplitude determined from a reference input signal amplitude for the serial ATA interfaces to produce a first comparison result; (d) determining, based on the first comparison result, an amplitude A1 of a serial data signal output from the first signal output device, such that when the serial data signal output from the first signal output device is input to the second signal input device via the serial ATA bus, the serial data signal received by the second signal input device has an amplitude equal to the expected input signal amplitude; (e) adjusting the amplitude A1 by multiplying the amplitude A1 by a coefficient, C1. less that one so that the first signal output device outputs a serial data signal having an amplitude C1A1, and the resulting serial data signal is transmitted over the serial ATA bus and is received as signal S2 by the second signal input device and has an amplitude less than the expected input signal amplitude; (f) transmitting a serial data signal S2 from the first signal output device to the second signal input device over the serial ATA bus; (g) detecting an amplitude of the signal S2 received by the second signal input device from the first signal output device; (h) comparing the detected amplitude of the signal S2 with an expected input signal amplitude determined from a reference input signal amplitude for the serial ATA interfaces to produce a second comparison result; (i) determining, based on the second comparison result, an amplitude A2 of a serial data signal output from the second signal output device, such that when the serial data signal output from the second signal output device is input to the first signal input device via the serial ATA bus, the serial data signal received by the first signal input device has an amplitude equal to the expected input signal amplitude; (j) adjusting the amplitude A2 by multiplying the amplitude A2 by a coefficient, C2. less that one so that the second signal output device outputs a serial data signal having an amplitude C2A2, and the resulting serial data signal is transmitted over the serial ATA bus and is received by the first signal input device and has an amplitude less than the expected input signal amplitude.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram illustrating the configuration of a system equipped with a magnetic disk drive (HDD), according to an embodiment of the invention;

FIG. 2 is a block diagram mainly illustrating the configurations of output signal amplitude adjusting units 13 and 23 and signal input/output circuits 121 and 221, which are incorporated in the system of FIG. 1;

FIG. 3 is a view illustrating reference amplitudes for the output and input signals of serial ATA interfaces;

FIG. 4 is a graph illustrating the relationship between the amplitude of a data signal at the receive side and the cable length of an SATA bus 30, when the amplitude of the data signal at the transmit side is 400 mV; and

FIG. 5 is a flowchart illustrating a procedure, performed in a modification of the embodiment, for adjusting the amplitude of an output signal using the output signal amplitude adjusting units 13 and 23.

### DETAILED DESCRIPTION OF THE INVENTION

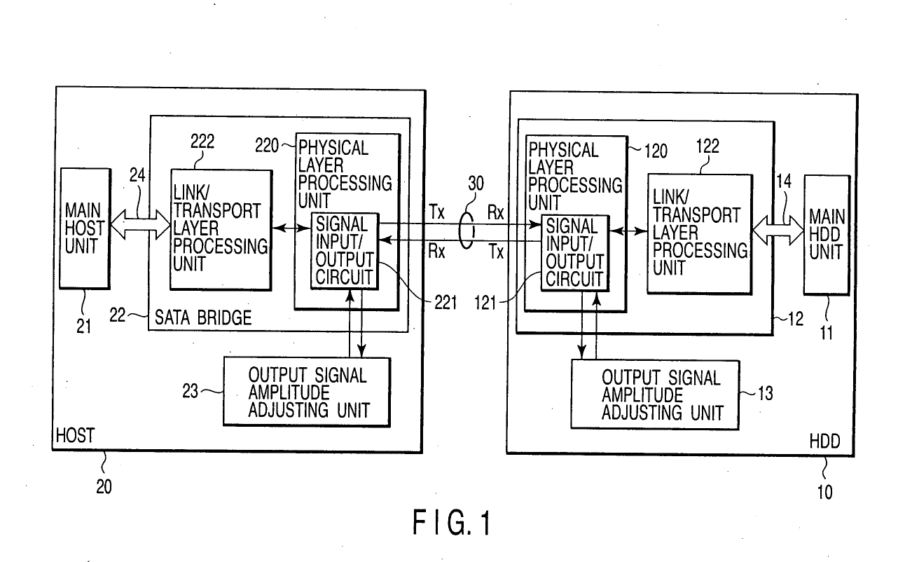

An embodiment in which the invention is applied to a system equipped with a magnetic disk drive having a serial ATA interface (hereinafter referred to as an “SATA”) will be described in detail with reference to the accompanying drawings. FIG. 1 is a block diagram illustrating the configuration of the system equipped with the magnetic disk drive (hereinafter referred to as an “HDD”), according to the embodiment of the invention. As shown, an HDD 10 comprises a main HDD unit 11, serial ATA bridge (hereinafter referred to as an “SATA bridge”) 12 and output signal amplitude adjusting unit 13. The main HDD unit 11 corresponds to a conventional HDD for performing parallel data transfer using an ATA interface. The SATA bridge 12 is formed of a one-chip LSI. The SATA bridge 12 functions as a SATA interface control circuit for performing interface conversion between an ATA interface and SATA interface.

The SATA bridge 12 is connected to a host 20 via a serial ATA bus (hereinafter referred to as an “SATA bus”) 30. The host 20 is an electronic device using the HDD 10 as a storage, such as a personal computer. The SATA bus 30 can have different lengths in accordance with different occasions of use. Depending upon whether, for example, the host 20 is a notebook-type personal computer or desktop-type computer, the length of the SATA bus 30 varies. The SATA bus 30 can be formed of a cable (electric wire) or wiring pattern. The wiring pattern can be formed on the printed circuit board of the host 20. In the embodiment, the length of the SATA bus 30 will be referred to as a “cable length” regardless of whether the bus 30 is formed of a cable or wiring pattern. The SATA bridge 12 is connected to the main HDD unit 11 via an ATA bus 14 compatible with the ATA interface standards.

The host 20 comprises a main host unit 21, SATA bridge 22 and output signal amplitude adjusting unit 23. The main host unit 21 corresponds to a conventional host for performing parallel data transfer using an ATA interface. The SATA bridge 22 is formed of a one-chip LSI, like the SATA bridge 12 of the HDD 10. The SATA bridge 22 functions as a SATA interface control circuit for performing interface conversion between an ATA interface and SATA interface. The SATA bridge 22 is connected to the HDD 10 via the SATA bus 30. The SATA bridge 22 is also connected to the main host unit 21 via an ATA bus 24. Buses, such as peripheral component interconnect (PCI) buses, compatible with the ATA buses 14 and 24 may be employed instead of the ATA buses 14 and 24. In this case, the SATA bridges (SATA interface control circuits) 12 and 22 can be provided in a PCI bridge.

The SATA bridges 12 and 22 have physical layer processing units 120 and 220 and link/transport layer processing units 122 and 222, respectively. The physical layer processing units 120 and 220 execute high-rate serial data transfer (transmission/reception) via the SATA bus 30. At this time, the data transfer rate is 1.5 Gbps (gigabits per second). The physical layer processing units 120 and 220 interpret data received from the SATA bus 30, and transmits the data to the link/transport layer processing units 122 and 222 in accordance with the interpretation results, respectively. Further, the physical layer processing units 120 and 220 transmit respective serial data signals in response to requests from the link/transport layer processing units 122 and 222, respectively. The physical layer processing units 120 and 220 include signal input/output circuits 121 and 221, respectively. The signal input/output circuits 121 and 221 receive and transmit serial data signals from and to the SATA bus 30. The link/transport layer processing units 122 and 222 each include a link layer processing unit and transport layer processing unit, which are not shown. The respective link layer processing units of the link/transport layer processing units 122 and 222 supply the physical layer processing units 120 and 220 with requests to output signals, in response to request from the transport layer processing units of the processing units 122 and 222. Further, the respective link layer processing units of the processing units 122 and 222 supply the respective transport layer processing units with data transmitted from the physical layer processing units 120 and 220. The transport layer processing units perform interface conversion between the ATA interface and SATA interface.

The output signal amplitude adjusting units 13 and 23 are connected to the signal input/output circuits 121 and 221 of the physical layer processing units 120 and 220, respectively. The output signal amplitude adjusting units 13 and 23 automatically adjust the amplitudes of serial data signals (output signal amplitudes, i.e., output levels) output from the signal input/output circuits 121 and 221. Automatic adjustment by the output signal amplitude adjusting units 13 and 23 is performed so that the amplitudes of serial data signals (input signal amplitudes, i.e., input levels) input to the signal input/output circuits 121 and 221 via the SATA bus 30 fit to the SATA interface standards regardless of the cable length of the SATA bus 30. However, the output signal amplitude adjusting units 13 and 23 cannot measure the amplitudes of serial data signals input to the signal input/output circuits 221 and 121, respectively. Therefore, the output signal amplitude adjusting units 13 and 23 measure the amplitudes of serial data signals input to the signal input/output circuits 121 and 221, respectively. From the measured amplitudes, they estimate the amplitudes of serial data signals input to the signal input/output circuits 221 and 121, respectively, which are incorporated in respective destination devices from and to which serial data signals are to be output and input.

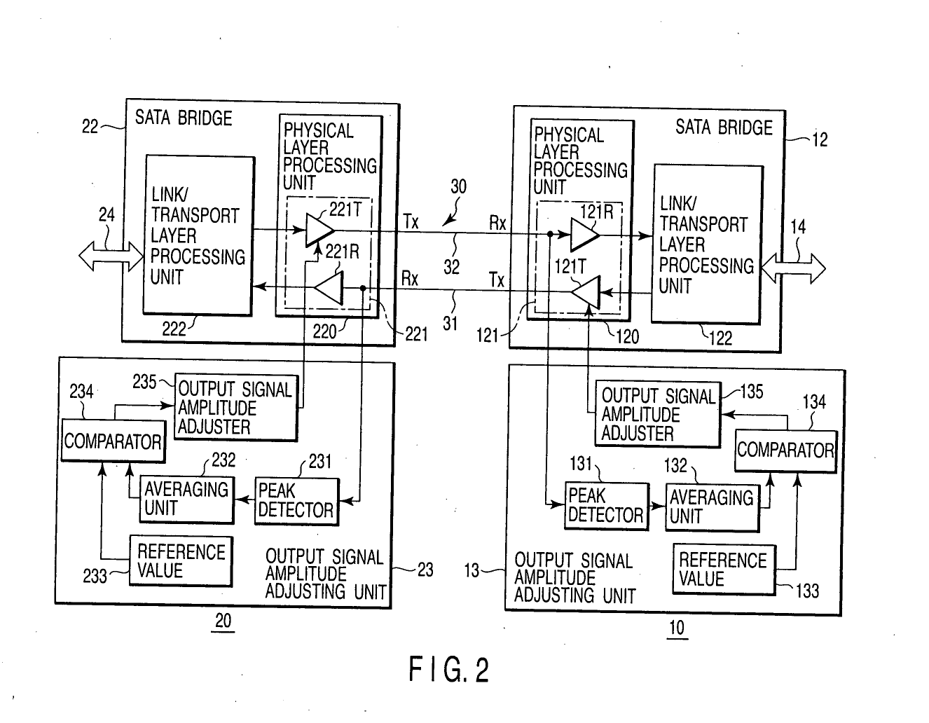

FIG. 2 mainly shows the configurations of the output signal amplitude adjusting units 13 and 23 and the signal input/output circuits 121 and 221. The signal input/output circuits 121 and 221 include output amplifiers (output drivers) 121T and 221T, input amplifiers 121R and 221R, respectively. The output amplifiers 121T and 221T amplify serial data signals output from the link/transport layer processing units 122 and 222, respectively, and output the amplified signals to the SATA bus 30. The input amplifiers 121R and 221R amplify serial data signals input thereto via the SATA bus 30, and supply the amplified signals to the link/transport layer processing units 122 and 222, respectively. The SATA bus 30 includes serial data transmission channels 31 and 32. The output terminal of the output amplifier 121T is connected to the input terminal of the input amplifier 221R via the serial data transmission channel 31, while the output terminal of the output amplifier 221T is connected to the input terminal of the input amplifier 121R via the serial data transmission channel 32. The amplifiers 121T, 121R, 221T and 221R are, for example, differential amplifiers. The serial transmission channels 31 and 32 are each formed of a pair of signal lines.

The output signal amplitude adjusting units 13 and 23 include peak detectors 131 and 231, averaging units 132 and 232, reference value storage devices 133 and 233, comparators 134 and 234, output signal amplitude adjusters 135 and 235, respectively. The peak detectors 131 and 231 detect the amplitudes (peak-to-peak amplitudes) of serial data signals (i.e., input signals) input to the input amplifiers 121R and 221R, respectively. The averaging units 132 and 232 hold the amplitudes detected by the peak detectors 131 and 231, respectively, and calculate the respective averages of the detection results of the detectors 131 and 231 obtained within a predetermined period. The reference value storage devices 133 and 233 store reference amplitudes for the input signals of the SATA interface.

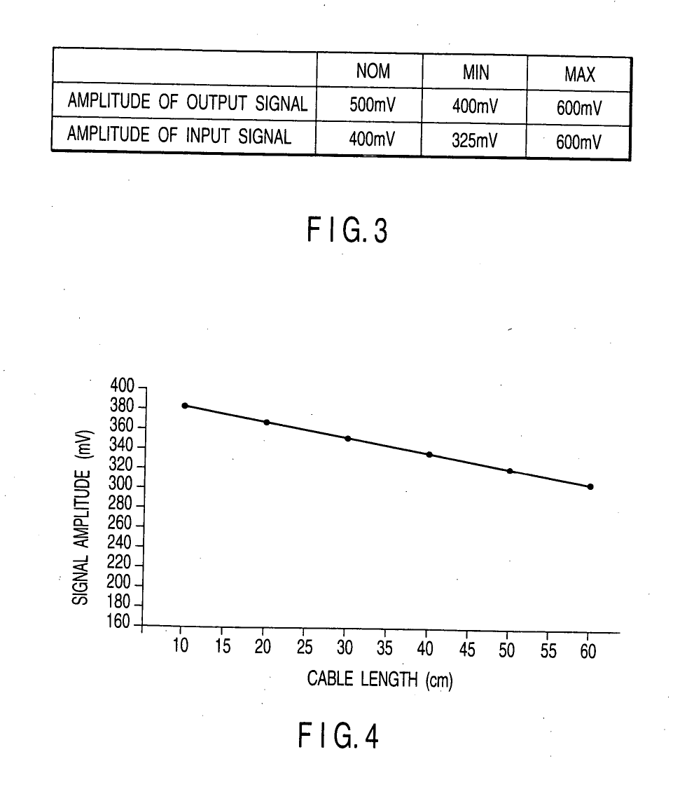

FIG. 3 shows reference amplitudes for the output and input signals of the SATA interface. As seen from FIG. 3, the amplitude standards for the output and input signals of the SATA interface stipulate the maximum amplitude (maximum level), minimum amplitude (minimum level) and nominal amplitude (recommended amplitude).

Referring again to FIG. 2, the comparators 134 and 234 compare the average values (i.e., the averages of the actually input signals) calculated by the averaging units 132 and 232, with the reference amplitudes (nominal amplitudes) for input signals stored in the reference value storage devices 133 and 233, respectively. The output signal amplitude adjusters 135 and 235 adjust the amplitudes of serial data signals (output signal amplitudes) output from the output amplifiers 121T and 221T, respectively, by controlling, for example, the gains of the output amplifiers 121T and 221T in accordance with the comparison results of the comparators 134 and 234, respectively.

A description will now be given of the operation of the embodiment, using, as an example, the operation of each of the output signal amplitude adjusting units 13 and 23 to automatically adjust the amplitude of a serial data signal output from each of the signal input/output units 121 and 221 to the SATA bus 30. This automatic adjustment operation is carried out when power is supplied from a power supply to the host 20 to turn on it. In the embodiment, the power supply for the host 20 is commonly used for the HDD 10. Accordingly, when the host 20 is turned on, the HDD 10 is also turned on.

As described above, the SATA bridge 22 of the host 20 has the signal input/output unit 221. Assume here that the output amplifier 221T of the signal input/output unit 221 supplies a serial data signal to the serial data transmission channel 32 at a rate of 1.5 Gbps. This serial data signal is transferred from the serial data transmission channel 32 to the HDD 10. The SATA bridge 12 of the HDD 10 has the signal input/output unit 121. The serial data signal transferred to the HDD 10 is input to the input amplifier 121R of the signal input/output unit 121. The serial data signal transferred via the serial data transmission channel 32 is attenuated because of the loss characteristic (attenuation characteristic) of the transmission channel 32. The attenuation depends upon the cable length of the transmission channel 32.

FIG. 4 shows changes in the amplitude of a serial data signal due to changes in the cable length of the SATA bus 30 at the receive side (i.e., at the input amplifier 121R of the signal input/output unit 121), the serial data signal being output from the output amplifier 221T of the signal input/output unit 221 to the input amplifier 121R. In the example of FIG. 4, the amplitude (peak-to-peak amplitude) of the serial data signal at the transmit side (at the output amplifier 221T) is 400 mV. 400 mV is the minimum level among the reference amplitudes (levels) stipulated for the input signals of serial SATA interfaces. As is evident from FIG. 4, even if the amplitudes of signals are constant at the transmit side, they vary at the receive side, depending upon the cable length. An attenuation in signal amplitude at the receive side increases as the cable length of the SATA bus 30 increases. That is, the longer the cable length, the larger the signal amplitude attenuation at the receive side, whereas the shorter the cable length, the smaller the signal amplitude attenuation at the receive side. If the amplitude of an output signal at the transmit side is not set to an appropriate value according to a signal attenuation corresponding to the cable length of the SATA bus 30, the amplitude of an input signal at the receive side will be deviated from an expected value. In this case, it is very possible that data cannot correctly be received at the receive side.

The serial data signal transferred to the HDD 10 via the serial data transmission channel 32 is input to both the input amplifier 121R of the signal input/output unit 121 and the peak detector 131 of the output signal amplitude adjusting unit 13. The peak detector 131 detects (measures) the peak value (i.e., the peak-to-peak amplitude) of the serial data signal transferred via the serial data transmission channel 32, using a constant sampling frequency (in the embodiment, 1.5 GHz) corresponding to the data transfer rate of the SATA bus 30. The amplitude detection result of the peak detector 131 is supplied to the averaging unit 132. The averaging unit 132 samples and holds amplitude detection results output from the peak detector 131, at regular intervals of, for example, 10 μs. In other words, the averaging unit 132 thins out the amplitude detection results. The peak detector 131 may detect the peak value of an input data signal at regular sampling cycles of, for example, 10 μs (i.e., at sampling frequency of 100 KHz), and the averaging unit 132 may acquire all the detection results from the peak detector 131. The averaging unit 132 executes, for a preset period (e.g. 10 ms), the operation of acquiring and holding the amplitude detection results of the peak detector 131. As a result, when the preset period has elapsed, the averaging unit 132 holds a constant number (in this embodiment, 100) of amplitude detection results. The averaging unit 132 then calculates the average of the constant number of amplitude detection results, i.e., the average of the amplitudes of the input signals measured by the peak detector 131. The calculated average of the input signal amplitudes is supplied from the averaging unit 132 to the comparator 134.

To enable the peak detector 131 to hold 100 amplitude detection results in the embodiment where the averaging unit 132 acquires the amplitude detection result at regular intervals of 10 μs, it is sufficient if 100 delay circuits for delaying the amplitude detection result at regular intervals of 10 μs are connected by cascade connection. Alternatively, first-in first-out (FIFO) buffer of 100 stages may be used.

The comparator 134 compares the average of the input signal amplitudes calculated by the averaging unit 132, with a reference amplitude for input signals, such as a nominal amplitude (i.e., an expected input signal amplitude), stored in the reference value storage device 133. The comparator 134 acquires the difference between the average and nominal amplitude as the comparison result. The nominal value, i.e., the nominal value for input signal amplitudes included in the SATA interface standards, is 400 mV as shown in FIG. 3. Accordingly, it is desirable to adjust the output signal amplitude using a device at the output side (transmit side), so that the input signal amplitude is equal to the nominal value of 400 mV. According to the SATA interface standards, the maximum and minimum amplitudes (levels) for input signals are 600 mV and 325 mV, respectively (see FIG. 3). In light of this, the average amplitude of input signals calculated by the averaging unit 132 may be compared with the mean value (600+325) mV/2 (=462.5 mV) of the reference maximum and minimum levels.

The comparison result of the comparator 134 is supplied to the output signal amplitude adjuster 135. Specifically, the difference between the average amplitude of input signals and an expected value (a nominal amplitude for input signals or the mean value as explained above) included in the SATA interface standards is supplied as the comparison result of the comparator 134 to the output signal amplitude adjuster 135. The average amplitude of input signals is the average, within a present period (10 ms), of the amplitudes of a serial data signal transferred via the serial data transmission channel 32 of the SATA bus 30 and to be actually input to the input amplifier 121R of the SATA bridge 12.

Based on the comparison result of the comparator 134, the output signal amplitude adjuster 135 estimates the signal attenuation characteristic of the SATA bus 30 (serial data transmission channel 32). This estimation is performed based on the assumption that the serial data signal output side device (host 20) outputs a serial data signal of an amplitude (output signal amplitude) according to the SATA interface standards, e.g. 400 mV or some other set value within the range of 400 mV-600 mV. In the embodiment, a nominal value is used as an output signal amplitude according to the SATA interface standards. Specifically, the nominal value as the output signal amplitude is 500 mV as shown in FIG. 3. As the output signal amplitude according to the SATA interface standards, the mean value of the maximum level of 600 mV and the minimum level of 400 mV (see FIG. 3) may be used. However, in the case of the SATA interface standards shown in FIG. 3, the mean value, (600+400) mV/2, of the maximum level of 600 mV and the minimum level of 400 mV is equal to the nominal value.

Based on the signal attenuation characteristic of the SATA bus 30 estimated from the comparison result of the comparator 134, the output signal amplitude adjuster 135 determines an optimal amplitude A for output signals (hereinafter referred to as an “optimal output signal amplitude”). The optimal output signal amplitude A is an amplitude which fits to the SATA interface standards, and with which a serial data signal output from the output amplifier 121T should be input to the signal input/output circuit 221 of the SATA bridge 22 of the host 20 via the SATA bus 30 (serial data transmission line 32). The output signal amplitude adjuster 135 controls the output amplifier 121T of the signal input/output circuit 121 so that its output signal has the determined amplitude A. In the embodiment, the gain of the signal input/output circuit 121 is adjusted so that the output signal has the determined amplitude A. As a result, the output signal amplitude of the signal input/output circuit 121 of the SATA bridge 12 is adjusted so that the amplitude of a signal input to the signal input/output circuit 221 of the SATA bridge 22 becomes an expected value, such as a nominal value (400 mV), which fits to the SATA interface standards.

The serial data signal output from the output amplifier 121T to the serial data transmission line 31 of the SATA bus 30 is attenuated by the transmission line 31 before it is input to the signal input/output circuit 221 of the SATA bridge 22 in the host 20. However, the serial data signal input to the signal input/output circuit 221 has its amplitude already adjusted by the output signal amplitude adjusting unit 13 when it is output from the HDD 10 to the SATA bus 30. Accordingly, the amplitude of the serial data signal input to the signal input/output circuit 221, i.e., the input signal amplitude, is substantially equal to the expected amplitude (substantially equal to the nominal value) that fits to the SATA interface standards.

In the embodiment, a serial data signal is transferred via the SATA bus 30 not only in the direction from the HDD 10 to the host 20, but also in the opposite direction from the host 20 to the HDD 10. In the latter case, it is sufficient if the output signal amplitude adjusting unit 23 of the host 20 performs the same automatic adjustment of the output signal amplitude as that performed by the output signal amplitude adjusting unit 13 of the HDD 10. If the output signal amplitude adjusting units 13 and 23 thus automatically adjust the amplitudes of output signals, the amplitudes of signals input to the signal input/output circuits 221 and 121 via the SATA bus 30, i.e., the input signal amplitudes, can be set to appropriate values that fit to the SATA interface standards.

The output signal amplitude adjusting units 13 and 23 can utilize a voltage or current regulation method to control the output amplifiers 121T and 221T so as to change the amplitudes of output signals. In the voltage regulation method, the amplitude of a signal input to the SATA bus 30 is changed. In the current regulation method, when a signal is input to the SATA bus 30, the amount of current which flows into the SATA bus 30 is changed. To utilize the voltage adjustment method, the output amplifiers 121T and 221T must be voltage-driven amplifiers. On the other hand, to utilize the current regulation method, the output amplifiers 121T and 221T must be current-driven amplifiers.

A voltage-driven amplifier only changes the output signal amplitude of a transmit side, and therefore has a simple structure. However, when a voltage-driven amplifier is used, the leading and trailing edges of a SATA signal as a high-frequency signal are influenced by the frequency characteristic of a SATA bus and the impedance of a receive side. As a result, the SATA signal delays. On the other hand, a current-driven amplifier changes the amount of current to be flown into the SATA bus. Accordingly, when a current-driven amplifier is used, SATA signals are not influenced by the frequency characteristic of the SATA bus and the impedance of the receive side. However, the structure of the current-driven amplifier is complex. In light of the above, if it is preferred to simplify the structure of an amplifier used, the voltage regulation method is utilized, while if stabilization of the output signal amplitude is preferred, the current regulation method is utilized.

[Modification]

A modification of the embodiment will be described. When both the output signal amplitude adjusting units 13 and 23 of the HDD 10 and host 20 automatically adjust the amplitudes of output signals, the following problem may occur. For example, assume that the amplitude of a serial data signal (input signal amplitude) input to the signal input/output circuit 221 of the host 20 abruptly reaches an expected value after the output signal amplitude adjusting unit 13 of the HDD 10 performs output signal amplitude adjustment. In this case, the output signal amplitude adjusting unit 23 of the host 20 operates to maintain the present output signal amplitude since the input signal amplitude of the signal input/output circuit 221 is an appropriate value. In other words, the output signal amplitude adjusting unit 23 of the host 20 does not perform output signal amplitude adjustment based on the signal attenuation characteristic of the SATA bus 30. Therefore, the amplitude of a serial data signal input to the signal input/output circuit 121 of the HDD 10 may not be an expected value. Further, the amplitude (output signal amplitude) of a serial data signal output from the signal input/output circuit 121 of the HDD 10 to the SATA bus 30 may greatly differ from that of a serial data signal output from the signal input/output circuit 221 of the host 20 to the SATA bus 30. This is the problem that may occur when both the output signal amplitude adjusting units 13 and 23 of the HDD 10 and host 20 perform output signal amplitude automatic adjustment.

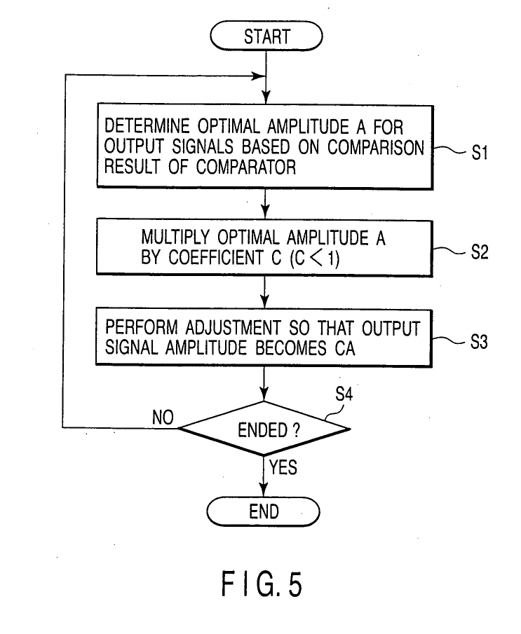

In light of this, the modification of the embodiment employs a technique for controlling one of the output signal amplitude adjusting units 13 and 23 to prevent the amplitude of an output signal from being abruptly adjusted to an appropriate value. This technique will be described with reference to the flowchart of FIG. 5. Firstly, the output signal amplitude adjusters 135 and 235 of the output signal amplitude adjusting units 13 and 23 determine respective optimal output signal amplitudes A1 and A2 based on the respective comparison results of the comparators 134 and 234 (step S1). The comparison results mean the respective differences between the averages of input signal amplitudes and an expected value (nominal value for input signal amplitudes) stipulated in the SATA interface standards.

Subsequently, the output signal amplitude adjusters 135 and 235 multiply the determined optimal output signal amplitudes A1 and A2 by a constant value, e.g., a preset coefficient C lower than 1, respectively (step S2). The output signal amplitude adjusters 135 and 235 control the output amplifiers 121T and 211T of the signal input/output circuits 121 and 221 so as to generate output signals having amplitudes that are equal to the amplification results CA1 and CA2 (step S3).

Thus, in the modification of the embodiment, the output signal amplitude adjusters 135 and 235 do not adjust the amplitudes of output signals to the optimal values A1 and A2, but to the values CA1 and CA2 (C<1) smaller than the optimal values A1 and A2, respectively. In this case, the input signal amplitudes of the signal input/output circuits 221 and 121 of the host 20 and HDD 10 do not abruptly reach an expected value. Accordingly, the output signal amplitude adjusting units 13 and 23 newly determine optimal output signal amplitudes A1′ and A2′ from the averages of the new input signal amplitudes of the signal input/output circuits 121 and 221, respectively (step S1). After that, the output signal amplitude adjusters 135 and 235 again adjust the amplitudes of output signals to values CA1′ and CA2′ smaller than the optimal values A1′ and A2′, respectively (steps S2 and S3).

As a further modification, separate coefficients C1 and C2 may be utilized for multiplying the respective amplitudes such the output signal values become C1A1, C2A2 and C1A1′, C2A2′ etc.

As described above, in the modification of the embodiment, the output signal amplitude adjusters 135 and 235 do not adjust the amplitudes of output signals to the optimal values that are expected in the signal input/output circuits 221 and 121 of the host 20 and HDD 10. Instead, the output signal amplitude adjusters 135 and 235 adjust the respective output signal amplitudes to the values acquired by multiplying the optimal output signal amplitudes by a preset coefficient C lower than 1. As a result, the amplitudes (output signal amplitudes) of the respective serial data signals output to the SATA bus 30 from the signal input/output circuits 121 and 221 of the HDD 10 and host 20 can be finally made substantially equal. The repetition of the steps S1 to S3 may be stopped (step S4) if, for example, the comparison results of the comparators 134 and 234 (i.e., the respective differences between the averages of input signal amplitudes and an expected value stipulated in the SATA interface standards) are lower than a constant value (preset threshold value). Alternatively, the repetition of the steps S1 to S3 may be stopped if a predetermined period has elapsed since the start of the process.

In the above-described embodiment, the output signal amplitude adjusting units 13 and 23 are provided independently of the main HDD unit 11 and main host unit 21. However, they may be incorporated in the main HDD unit 11 and main host unit 21. Further, the output signal amplitude adjusting unit 13 may be incorporated in a disk controller (HDC), not shown, in the main HDD unit 11, i.e., an HDC connected to the SATA bridge 12 via the SATA bus 14. Furthermore, the functions that are realized by the averaging units 132 and 232 and comparators 134 and 234, which are incorporated in the output signal amplitude adjusting units 13 and 23, can be realized by CPUs (not shown), employed in the main HDD unit 11 and host 20, in substitution for the mentioned units.

The above-described embodiment is directed to a system equipped with an HDD (magnetic disk drive). However, the present invention is also applicable to a system equipped with another type of disk drive, such as an optical disk drive, magneto-optical disk drive, etc. It is sufficient if the disk drive has a SATA interface. The present invention is further applicable to a system equipped with an electronic device other than disk drives, if only the electronic device has a SATA interface.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An electronic device with a serial ATA interface, comprising:
a signal output device for outputting a serial data signal to a serial ATA bus connecting the electronic device to another electronic device, the serial data signal to be transferred to said another electronic device, said another electronic device having a serial ATA interface;
a signal input device for receiving a serial data signal transferred from said another electronic device via the serial ATA bus;
a peak detection circuit for detecting an amplitude of the serial data signal received by the signal input device;
an averaging circuit for averaging amplitude detection results of the peak detection circuit;
a comparison device for comparing an averaging result of the averaging circuit with an expected input signal amplitude; and
an amplitude adjuster for adjusting, based on a comparison result of the comparison device, an amplitude of the serial data signal output by said signal output device such that when the serial data signal output from the signal output device is input to said another electronic device via the serial ATA bus, the input serial data signal has an amplitude at least approximately equal to the expected input signal amplitude.

2. The electronic device according to claim 1, wherein the amplitude adjusting circuit including:
determination means for determining an amplitude of the serial data signal output by the signal output device, said amplitude determined such that the serial data signal output by the signal output device and passing through said serial ATA bus and then received by an input device of said another electronic device has an amplitude as received by said input device of said another electronic device equal to the expected input signal amplitude; and
means for controlling the signal output device to cause the serial data signal output by said signal output device to have the amplitude determined by the determination means.

3. The electronic device according to claim 1, wherein the amplitude adjusting means including:
determination means for determining an amplitude of the serial data signal output by the signal output device, said amplitude determined such that the serial data signal output by the signal output device and passing through said serial ATA bus and then received by an input device of said another electronic device has an amplitude as received by said input device of said another electronic device equal to the expected input signal amplitude; and
means for multiplying the amplitude determined by the determination means by a preset coefficient less than 1; and
means for controlling the signal output device to cause the serial data signal output by said signal output device to have an amplitude acquired by multiplying the amplitude determined by the determination means by the preset coefficient.

4. The electronic device according to claim 1, wherein the peak detection circuit detects the amplitude of the serial data signal received by the signal input device, at a sampling frequency corresponding to a data transfer rate of the serial ATA bus.

5. The electronic device according to claim 1, wherein the comparison device uses, as the expected input signal amplitude, a nominal input signal amplitude stipulated in standards for the serial ATA interfaces.

6. The electronic device according to claim 1, wherein the comparison device uses, as the expected input signal amplitude, an intermediate value between a maximum input signal amplitude and a minimum input signal amplitude, the maximum input signal amplitude and the minimum input signal amplitude being stipulated in standards for the serial ATA interfaces.

7. A system comprising:
a first electronic device having a serial ATA interface;
a second electronic device having a serial ATA interface; and
a serial ATA bus connecting the first electronic device to the second electronic device,
wherein the first electronic device includes:
a first signal output device for outputting, to the serial ATA bus, a serial data signal to be transferred to the second electronic device;
a first signal input device for receiving a serial data signal transferred from the second electronic device via the serial ATA bus;
a first peak detection circuit for detecting an amplitude of the serial data signal received by the first signal input device;
a first averaging circuit for averaging amplitude detection results of the first peak detection circuit;
a first comparison device for comparing an averaging result of the first averaging circuit with an expected input signal amplitude determined from a reference input signal amplitude for the serial ATA interfaces; and
a first amplitude adjuster for adjusting, based on a comparison result of the first comparison device, an amplitude of the serial data signal output by said first signal output device such that when the serial data signal output from the first signal output device is input to the second electronic device via the serial ATA bus, the input serial data signal has an amplitude at least approximately equal to the expected input signal amplitude,
and wherein the second electronic device includes:
a second signal output device for outputting, to the serial ATA bus, the serial data signal output by said second signal output device;
a second signal input device for receiving the serial data signal output from the first signal output device via the serial ATA bus;
a second peak detection circuit for detecting an amplitude of the serial data signal received by the second signal input device;
a second averaging circuit for averaging amplitude detection results of the second peak detection circuit;
a second comparison device for comparing an averaging result of the second averaging circuit with the expected input signal amplitude; and
a second amplitude adjuster for adjusting, based on a comparison result of the second comparison device, an amplitude of serial data signal output by said second signal output device such that when the serial data signal output from the second signal output device is input to the first electronic device via the serial ATA bus, the input serial data signal has an amplitude at least approximately equal to the expected input signal amplitude.

8. The system according to claim 7, wherein the first amplitude adjuster including:
first determination means for determining an amplitude of the serial data signal output by the first signal output device, said amplitude determined such that the serial data signal output by the first signal output device and passing through said serial ATA bus and then received by the second signal input device has an amplitude as received by said second signal input device at least approximately equal to the expected input signal amplitude; and
means for controlling the first signal output device to cause the serial data signal output by said first signal output device to have the amplitude determined by the first determination means,
and wherein the second amplitude adjuster includes:
second determination means for determining an amplitude of the serial data signal output by the second signal output device, said amplitude determined such that the serial data signal output by the second signal output device and passing through said serial ATA bus and then received by the first signal input device has an amplitude as received by said first signal input device at least approximately equal to the expected input signal amplitude; and
means for controlling the second signal output device to cause the serial data signal output by said second signal output device to have the amplitude determined by the second determination means.

9. The system according to claim 7, wherein the amplitude adjuster includes:
first determination means for determining an amplitude of the serial data signal output by the first signal output device, said amplitude determined such that the serial data signal output by the first signal output device and passing through said serial ATA bus and then received by the second signal input device has an amplitude as received by said second signal input device at least approximately equal to the expected input signal amplitude; and
first multiplication means for multiplying the amplitude determined by the first determination means by a preset coefficient less than 1; and
means for controlling the first signal output device to cause the serial data signal output by said first signal output device to have an amplitude acquired by multiplying the amplitude determined by the first determination means by the preset coefficient,
and wherein the second amplitude adjuster includes:
second determination means for determining an amplitude of the serial data signal output by the second signal output device, said amplitude determined such that the serial data signal output by the second signal output device and passing through said serial ATA bus and then received by the first signal input device has an amplitude as received by said first signal input device at least approximately equal to the expected input signal amplitude; and
second multiplication means for multiplying the amplitude determined by the second determination means by a preset coefficient less than 1; and
means for controlling the second signal output device to cause the serial data signal output by said second signal output device to have an amplitude acquired by multiplying the amplitude determined by the second determination means by the preset coefficient.

10. A method of automatically adjusting an output signal amplitude, the method being employed in a system in which a first electronic device with a serial ATA interface is connected to a second electronic device with a serial ATA interface via a serial ATA bus, the first electronic device including a signal output device for outputting a serial data signal to the serial ATA bus, and a signal input device for receiving a serial data signal transferred from the second electronic device via the serial ATA bus, the output signal amplitude being an amplitude of the serial data signal output from the signal output device to the serial ATA bus, the method comprising:
detecting an amplitude of the serial data signal received by the signal input device, at a sampling frequency, said detecting performed during a predetermined time period;
averaging amplitudes detected during the predetermined period;
comparing an average acquired by the averaging with an expected input signal amplitude determined from a reference input signal amplitude for the serial ATA interfaces to produce a comparison result; and
adjusting, based on the comparison result, an amplitude of a serial data signal output from the signal output device, such that when the serial data signal output from the signal output device is input to the second electronic device via the serial ATA bus, the input serial data signal has an amplitude at least approximately equal to the expected input signal amplitude.

11. The method according to claim 10, wherein the adjusting includes:
determining an amplitude of the serial data signal output by the signal output device such that the serial data signal output by the signal output device and passing through said serial ATA bus and then received by an input device of the second electronic device has an amplitude equal to the expected input signal amplitude; and
controlling the signal output device to cause the serial data signal output by said signal output device to have the determined amplitude.

12. The method according to claim 10, wherein the adjusting including:
determining an amplitude of the serial data signal output by the signal output device such that the serial data signal output by the signal output device and passing through said serial ATA bus and then received by an input device of the second electronic device has an amplitude equal to the expected input signal amplitude; and
multiplying the determined amplitude by a preset coefficient less than 1; and
controlling the signal output device to cause the serial data signal output by said signal output device to have an amplitude acquired by multiplying the determined amplitude by the preset coefficient.

13. An electronic device with a serial ATA interface comprising:
a signal output device for outputting a serial data signal to a serial ATA bus connecting the electronic device to another electronic device, the serial data signal to be transferred to said another electronic device, said another electronic device having a serial ATA interface;
a signal input device for receiving a serial data signal transferred from said another electronic device via the serial ATA bus;
a detection circuit for detecting an amplitude of the serial data signal received by the signal input device;
a comparison device for comparing the detected amplitude with an expected input signal amplitude; and
an amplitude adjuster for determining, based on a comparison result of the comparison device, an amplitude A of the serial data signal output by said signal output device such that when the serial data signal output from the signal output device is input to said another electronic device via the serial ATA bus, the input serial data signal has an amplitude approximately equal to the expected input signal amplitude, said amplitude adjuster multiplying the amplitude A by a coefficient less than one so that the input serial data signal amplitude is CA which is less than the expected input signal amplitude.

14. A method of automatically adjusting an output signal amplitude, the method being employed in a system in which a first electronic device with a serial ATA interface is connected to a second electronic device with a serial ATA interface via a serial ATA bus, the first electronic device including a first signal output device, and a first signal input device, and the second electronic device including a second signal output device, and a second signal input device, the method comprising:
(a) transmitting a serial data signal S1 from the second signal output device to the first signal input device over said serial ATA bus;
(b) detecting an amplitude of the serial data signal S1 received by the first signal input device from the second signal output device;
(c) comparing the detected amplitude with an expected input signal amplitude determined from a reference input signal amplitude for the serial ATA interfaces to produce a first comparison result;
(d) determining, based on the first comparison result, an amplitude A1 of a serial data signal output from the first signal output device, such that when the serial data signal output from the first signal output device is input to the second signal input device via the serial ATA bus, the serial data signal received by the second signal input device has an amplitude equal to the expected input signal amplitude;
(e) adjusting the amplitude A1 by multiplying the amplitude A1 by a coefficient, C1. less that one so that the first signal output device outputs a serial data signal having an amplitude C1A1, and the resulting serial data signal is transmitted over said serial ATA bus and is received as signal S2 by said second signal input device and has an amplitude less than the expected input signal amplitude;
(f) transmitting a serial data signal S2 from the first signal output device to the second signal input device over said serial ATA bus;
(g) detecting an amplitude of the signal S2 received by the second signal input device from the first signal output device;
(h) comparing the detected amplitude of the signal S2 with an expected input signal amplitude determined from a reference input signal amplitude for the serial ATA interfaces to produce a second comparison result;
(i) determining, based on the second comparison result, an amplitude A2 of a serial data signal output from the second signal output device, such that when the serial data signal output from the second signal output device is input to the first signal input device via the serial ATA bus, the serial data signal received by the first signal input device has an amplitude equal to the expected input signal amplitude;
(j) adjusting the amplitude A2 by multiplying the amplitude A2 by a coefficient, C2. less that one so that the second signal output device outputs a serial data signal having an amplitude C2A2, and the resulting serial data signal is transmitted over said serial ATA bus and is received by said first signal input device and has an amplitude less than the expected input signal amplitude.

15. The method as recited in claim 14, further comprising repeating steps (a) through (j) a plurality of times where on each repeat, the signal S1 has the amplitude A2, and the signal S2 has the amplitude A1.

16. The method as recited in claim 15 wherein C1 is equal to C1.

17. The method as recited in claim 14 wherein C1 is equal to C1.
